(19) United States
(12) Patent Application Publication
(10) Pub. No.: US 2023/0072487 A1
(43) Pub. Date: Mar. 9, 2023

(54) BULK-ACOUSTIC WAVE RESONATOR

(71) Applicant: SAMSUNG ELECTRO-MECHANICS CO., LTD., Suwon-si (KR)

(72) Inventors: Won HAN, Suwon-si (KR); Hwa Sun LEE, Suwon-si (KR); Moon Chul LEE, Suwon-si (KR); Jeong Hoon RYOU, Suwon-si (KR); Tae Yoon KIM, Suwon-si (KR); Sang Kee YOON, Suwon-si (KR); Yong Suk KIM, Suwon-si (KR); Joung Hun KIM, Suwon-si (KR); Tae Kyung LEE, Suwon-si (KR); Jae Hyoung GIL, Suwon-si (KR)

(73) Assignee: SAMSUNG ELECTRO-MECHANICS CO., LTD., Suwon-si (KR)

(21) Appl. No.: 17/676,905

(22) Filed: Feb. 22, 2022

(30) Foreign Application Priority Data
Aug. 30, 2021 (KR) 10-2021-0114377

(51) Int. Cl. H03H 9/02; H03H 3/04; H03H 9/17

(52) U.S. Cl. CPC H03H 9/02102; H03H 3/04; H03H 9/02031; H03H 9/174; H03H 9/176; H03H 2003/0407

(57) ABSTRACT

A bulk acoustic wave resonator is provided. The bulk acoustic wave resonator includes a board; a resonant portion including a first electrode, a piezoelectric layer, and a second electrode, and disposed on the board, and a temperature compensation layer disposed on the resonant portion, wherein the temperature compensation layer includes a temperature compensation portion formed of a dielectric and a loss compensation portion formed of a material different from a material of the temperature compensation portion, and wherein each of the temperature compensation portion and the loss compensation portion includes a plurality of linear patterns, and the linear patterns of the temperature compensation portion and the linear patterns of the loss compensation portion are alternately disposed.

### CROSS-REFERENCE TO RELATED APPLICATIONS

This application claims the benefit under 35 USC § 119(a) of Korean Patent Application No. 10-2021-0114377, filed on Aug. 30, 2021, in the Korean Intellectual Property Office, the entire disclosure of which is incorporated herein by reference for all purposes.

### BACKGROUND

### 1. Field

The following description relates to a bulk-acoustic wave resonator.

### 2. Description of Related Art

In accordance with the trend to miniaturize wireless communications devices, there has been increasing demand for the miniaturization of high-frequency components. To that extent, a bulk acoustic wave resonator (BAW) type filter based on the technique of manufacturing a semiconductor thin film wafer has been implemented.

A bulk acoustic wave resonator (BAW) may refer to a thin film device configured as a filter, which may generate resonance using piezoelectric properties by depositing a piezoelectric dielectric material on a silicon wafer, a semiconductor board.

However, in the example of 5G communications using a sub 6 GHz (4 to 6 GHz) frequency band, the bandwidth may increase and the communication distance may be shortened, such that the strength or power of a signal may increase.

Also, the temperature of a piezoelectric layer or a resonant portion may increase as the power increases. In this example, the frequency of the resonator may fluctuate due to the high temperature, such that the stability of a bulk acoustic wave resonator may be deteriorated.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a bulk acoustic wave resonator includes a board; a resonant portion comprising a first electrode, a piezoelectric layer, and a second electrode disposed on the board; and a temperature compensation layer disposed on the resonant portion, wherein the temperature compensation layer comprises a temperature compensation portion formed of a dielectric, and a loss compensation portion formed of a material different from a material of the temperature compensation portion, and wherein each of the temperature compensation portion and the loss compensation portion comprises a plurality of linear patterns, and the linear patterns of the temperature compensation portion and the linear patterns of the loss compensation portion are alternately disposed.

A sum of a width of a unit pattern of the temperature compensation portion and a width of a unit pattern of the loss compensation portion may be configured to be less than a wavelength of a lateral wave generated in the resonant portion.

A sum of a width of a unit pattern of the temperature compensation portion and a width of a unit pattern of the loss compensation portion may be configured to be 0.8 μm or less.

One of a width of the unit pattern of the temperature compensation portion and a width of the unit pattern of the loss compensation portion may be configured to be 0.4 μm or less.

A sum of a width of a unit pattern of the temperature compensation portion and a width of a unit pattern of the loss compensation portion may be configured to be 1.6 μm or less.

One of a width of the unit pattern of the temperature compensation portion and a width of the unit pattern of the loss compensation portion may be configured to be 0.8 μm or less.

A sum of a width of a unit pattern of the temperature compensation portion and a width of a unit pattern of the loss compensation portion may be 80% or less of a wavelength of a lateral wave generated in the resonant portion.

One of a width of the unit pattern of the temperature compensation portion and a width of the unit pattern of the loss compensation portion may be 40% or less of a wavelength of a lateral wave generated in the resonant portion.

The temperature compensation portion may include SiO₂.

The loss compensation portion may be formed of the same material as a material of one of the piezoelectric layer, the first electrode, and the second electrode.

The loss compensation portion may be formed of aluminum nitride (AlN) or scandium doped AlN (ScAlN).

The loss compensation portion may be formed of one of a piezoelectric material and a metal.

The temperature compensation layer may be disposed between the first electrode and the piezoelectric layer, or between the second electrode and the piezoelectric layer.

Each of the linear patterns of the temperature compensation portion and each of the linear patterns of the loss compensation portion may be configured to have a concentric annular shape.

A plane of the resonant portion may be configured to have a polygonal shape, and the linear patterns of the temperature compensation portion and the linear patterns of the loss compensation portion may be disposed parallel to one of sides forming the polygonal shape.

In a general aspect, a bulk acoustic wave resonator includes a board; a resonant portion comprising a first electrode, a piezoelectric layer, and a second electrode which are sequentially disposed on the board; and a temperature compensation layer disposed on the resonant portion, wherein the temperature compensation layer includes a temperature compensation portion and a loss compensation portion alternately disposed linearly, and the temperature compensation portion is formed of a material having a positive temperature coefficient of elastic constant (TCE), and the loss compensation portion is formed of a material having a negative TCE.

The temperature compensation layer may be disposed above the piezoelectric layer, below the piezoelectric layer, or in the piezoelectric layer, and the piezoelectric layer may be formed of a material having a negative TCE.

The piezoelectric layer may be formed of aluminum nitride (AlN), and the loss compensation portion is formed of scandium doped AlN (ScAlN).

Other features and aspects will be apparent from the following detailed description, the drawings, and the claims.

### BRIEF DESCRIPTION OF DRAWINGS

FIG. 1 is a plan diagram illustrating an example bulk acoustic wave resonator, in accordance with one or more embodiments.

FIG. 2 is a cross-sectional diagram taken along I-I′ in FIG. 1.

FIG. 3 is a cross-sectional diagram taken along II-II′ in FIG. 1.

FIG. 4 is a cross-sectional diagram taken along III-III′ in FIG. 1.

FIG. 5 is an enlarged cross-sectional diagram illustrating portion A in FIG. 2.

FIGS. 6 and 7 are diagrams illustrating changes in an impedance waveform according to presence or absence of a temperature compensation layer and changes in a size of a pattern, in accordance with one or more embodiments.

FIGS. 8A to 8C illustrate plan diagrams of a temperature compensation layer, in accordance with one or more embodiments.

FIG. 9 is a table of data of TCF, kₜ², and Q values according to changes in a thickness of a temperature compensation layer in a resonant frequency band of 3.55 GHz, in accordance with one or more embodiments.

FIG. 10 is a table of data of TCF, kₜ², and Q values according to changes in a thickness of a temperature compensation layer in a resonant frequency band of 1.75 GHz, in accordance with one or more embodiments.

FIGS. 11A and 11B illustrate a cross-sectional diagram of an example bulk acoustic wave resonator, in accordance with one or more embodiments.

FIG. 12 is a diagram illustrating an example method of manufacturing an example bulk acoustic wave resonator, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

Also, in the description of example embodiments, detailed description of structures or functions that are thereby known after an understanding of the disclosure of the present application will be omitted when it is deemed that such description will cause ambiguous interpretation of the example embodiments.

Hereinafter, examples will be described in detail with reference to the accompanying drawings, and like reference numerals in the drawings refer to like elements throughout.

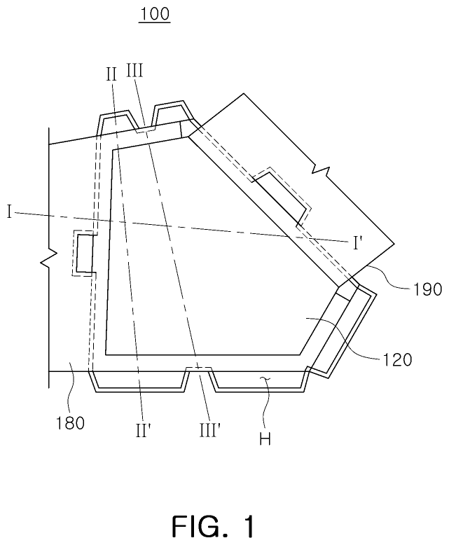

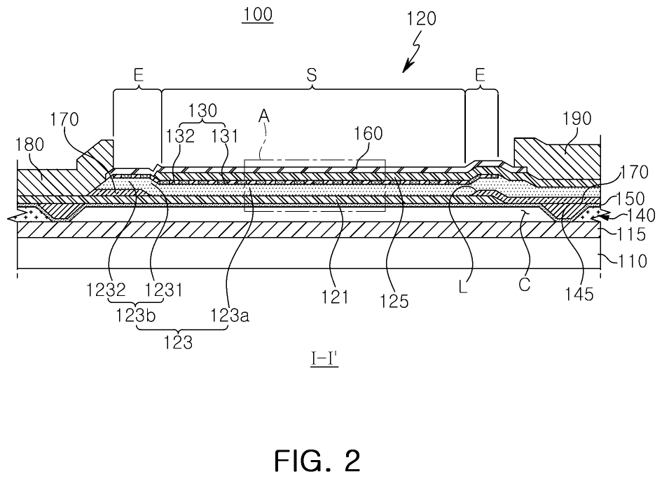

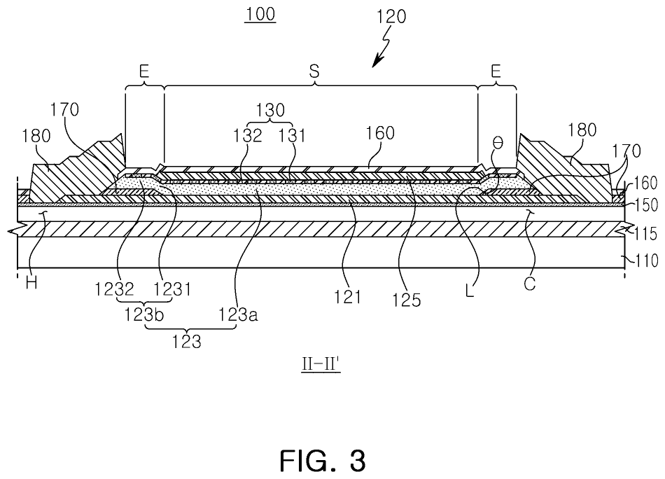

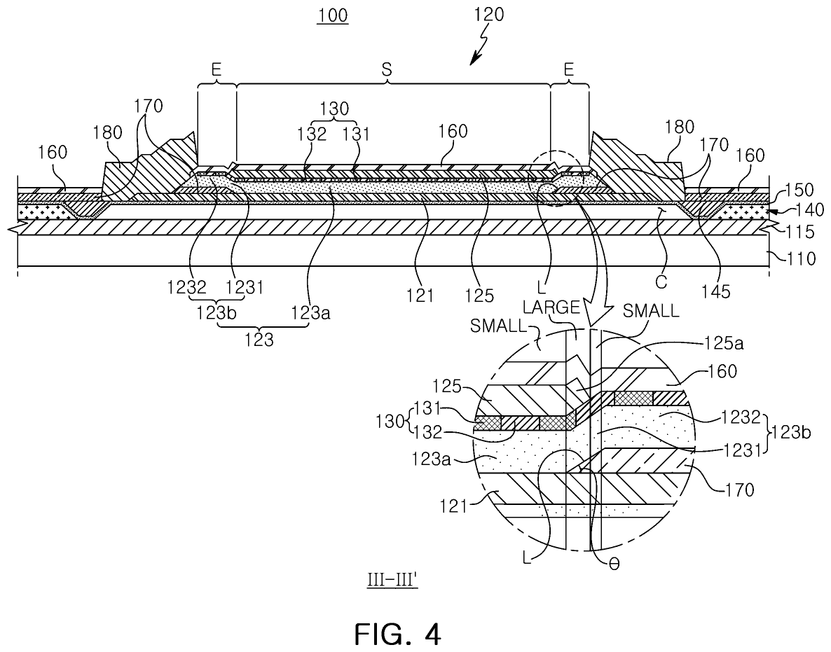

FIG. 1 is a plan diagram illustrating an example bulk acoustic wave resonator, in accordance with one or more embodiments. FIG. 2 is a cross-sectional diagram taken along I-I′ in FIG. 1. FIG. 3 is a cross-sectional diagram taken along II-II′ in FIG. 1. FIG. 4 is a cross-sectional diagram taken along III-III′ in FIG. 1.

Referring to FIGS. 1 to 4, an example acoustic resonator 100 may be implemented as a bulk acoustic wave resonator (BAW), and may include a board 110, a support layer 140, a resonant portion 120 and an insertion layer 170. Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

The board 110 may be configured as a silicon board. In a non-limited example, a silicon wafer or a silicon on insulator (SOI) type board may be used as the board 110.

An insulating layer 115 may be disposed on an upper surface of the board 110 and may electrically isolate the board 110 from the resonant portion 120. Additionally, the insulating layer 115 may prevent the board 110 from being etched by an etching gas when the cavity C is formed during the manufacturing process of the acoustic resonator.

In this example, the insulating layer 115 may be formed of at least one of silicon dioxide (SiO₂), silicon nitride (Si₃N₄), aluminum oxide (Al₂O₃), and aluminum nitride (AlN), and may be formed by one of chemical vapor deposition, RF magnetron sputtering, and evaporation processes, as only examples.

The support layer 140 may be formed on the insulating layer 115, and may be disposed around the cavity C and the etch stop portion 145 by surrounding the cavity C and the etch stop portion 145.

The cavity C may be formed as a void, and may be formed by removing a portion of a sacrificial layer formed in the process of preparing the support layer 140.

The etch stop portion 145 may be disposed along a boundary of the cavity C. The etch stop portion 145 may be provided to prevent etching beyond the cavity region during the process of forming the cavity C.

The membrane layer 150 may be formed on the support layer 140 and may form an upper surface and a side surface of the cavity C. Accordingly, the membrane layer 150 may also be formed of a material not easily removed in the process of forming the cavity C.

In an example, when a halide etching gas such as fluorine (F) or chlorine (CI) is used to remove a portion (e.g., the cavity region C) of the support layer 140, the membrane layer 150 may be formed of a material having low reactivity with the etching gas. In this example, the membrane layer 150 may include at least one of silicon dioxide (SiO2) and silicon nitride (Si3N4).

Additionally, the membrane layer 150 may be configured as a dielectric layer including at least one of magnesium oxide (MgO), zirconium oxide (ZrO2), aluminum nitride (AlN), lead zirconate titanate (PZT), gallium arsenide (GaAs), hafnium oxide (HfO2), aluminum oxide (Al2O3), titanium oxide (TiO2), or zinc oxide (ZnO), or may be configured ad a metal layer including at least one of aluminum (Al), nickel (Ni), chromium (Cr), platinum (Pt), gallium (Ga), and hafnium (Hf). However, is the one or more examples are not limited thereto.

The resonant portion 120 may include a first electrode 121, a piezoelectric layer 123, and a second electrode 125. In the resonant portion 120, the first electrode 121, the piezoelectric layer 123, and the second electrode 125 may be laminated in order from the bottom to the top. Accordingly, in the resonant portion 120, the piezoelectric layer 123 may be disposed between the first electrode 121 and the second electrode 125.

Since the resonant portion 120 may be formed on the membrane layer 150, the membrane layer 150, the first electrode 121, the piezoelectric layer 123 and the second electrode 125 may be laminated, and may form the resonant portion 120.

The resonant portion 120 may generate a resonant frequency and an anti-resonant frequency by resonating the piezoelectric layer 123 in response to a signal applied to the first electrode 121 and the second electrode 125.

The resonant portion 120 may include a central portion S in which the first electrode 121, the piezoelectric layer 123, and the second electrode 125 are laminated to have a flat form factor, and an extension portion E in which the insertion layer 170 is interposed between the electrode 121 and the piezoelectric layer 123.

The central portion S may be disposed in the center of the resonator portion 120 and the extension portion E may be disposed along the periphery of the central portion S. Accordingly, the extension portion E may extend outwardly from the central portion S, and may refer to a region formed in a continuous ring shape along the periphery of the central portion S. However, if desired, partial regions may be formed in a discontinuous ring shape.

Accordingly, as illustrated in FIG. 2, on the cross-sectional surface of the resonant portion 120 to cross the central portion S, the extension portion E may be disposed on each of both ends of the central portion S. Additionally, the insertion layer 170 may be disposed on each of both sides of the extension portion E disposed on both ends of the central portion S.

The insertion layer 170 may include an inclined surface L having a thickness that increases in the direction that extends away from the central portion S.

In the extension portion E, the piezoelectric layer 123 and the second electrode 125 may be disposed on the insertion layer 170. Accordingly, the piezoelectric layer 123 and the second electrode 125 disposed in the extension portion E may have inclined surfaces along the shape of the insertion layer 170.

In the example, the extension portion E may be included in the resonant portion 120, and accordingly, resonance may be performed in the extension portion E as well. However, the examples thereof are not limited thereto, and, resonance may not be performed in the extension portion E, but may only be performed in the central portion S depending on the structure of the extension portion E.

The first electrode 121 and the second electrode 125 may be formed of a conductor, and may be formed of, as only examples, gold, molybdenum, ruthenium, iridium, aluminum, platinum, titanium, tungsten, palladium, tantalum, chromium, nickel or a metal including at least one of the above-mentioned elements, but the examples are not limited thereto.

In the resonant portion 120, the first electrode 121 may be configured to have an area larger than an area of the second electrode 125, and the first metal layer 180 may be disposed along an outer edge of the first electrode 121 on the first electrode 121. Accordingly, the first metal layer 180 may be spaced apart from the second electrode 125 by a predetermined distance, and may surround the resonant portion 120.

Since the first electrode 121 may be disposed on the membrane layer 150, the first electrode 121 may be formed to be flat, whereas, since the second electrode 125 is disposed on the piezoelectric layer 123, a curve may be formed on at least one end of the second electrode 125 to correspond to the shape of the piezoelectric layer 123.

The first electrode 121 may be implemented as one of an input electrode and an output electrode to input and output an electrical signal such as a radio frequency (RF) signal.

The second electrode 125 may be disposed in the entire central portion S, and may be partially disposed in the extension portion E. Accordingly, the second electrode 125 may be divided into a portion disposed on a piezoelectric portion 123a of the piezoelectric layer 123, and a portion disposed on a bent portion 123b of the piezoelectric layer 123.

More specifically, in the example, the second electrode 125 may be disposed to cover the entire piezoelectric portion 123a and a portion of the inclined portion 1231 of the piezoelectric layer 123. Accordingly, the second electrode 125a (in FIG. 4) disposed in the extension portion E may have an area smaller than the area of the inclined surface of the inclined portion 1231, and the second electrode 125 in the resonant portion 120 may have an area smaller than the area of the piezoelectric layer 123.

Accordingly, as illustrated in FIG. 2, on the cross-sectional surface of the resonant portion 120 crossing the central portion S, an end of the second electrode 125 may be disposed in the extension portion E. Additionally, an end of the second electrode 125 disposed in the extension portion E may partially overlap the insertion layer 170. The configuration in which the extension portion E may partially overlap the insertion layer 170 indicates that, when the second electrode 125 is projected on the plane on which the insertion layer 170 is disposed, the shape of the second electrode 125 projected on the plane may overlap the insertion layer 170. Accordingly, the end of the second electrode 125 may be disposed on the inclined portion.

The second electrode 125 may be implemented as one of an input electrode and an output electrode to input and output an electrical signal such as a radio frequency (RF) signal. That is, when the first electrode 121 is used as an input electrode, the second electrode 125 may be used as an output electrode, and when the first electrode 121 is used as an output electrode, the second electrode 125 may be used as an input electrode.

As illustrated in FIG. 4, when the end of the second electrode 125 is disposed on the inclined portion 1231 of the piezoelectric layer 123, a local structure of acoustic impedance of the resonant portion 120 may be formed in a small/large/small structure from the central portion S, such that reflectance of reflecting a lateral wave into the resonant portion 120 may increase. Accordingly, most of the lateral waves may not escape the resonant portion 120 and may be reflected into the resonant portion 120, such that the performance of the acoustic resonator may improve.

In an example, the lateral wave may include a wave traveling along the direction of the plane of the resonant portion and forming spurious resonance.

The piezoelectric layer 123 may be configured to generate a piezoelectric effect V converting electrical energy into mechanical energy in the form of acoustic waves, and may be formed on the first electrode 121 and the insertion layer 170.

As the material of the piezoelectric layer 123, zinc oxide (ZnO), aluminum nitride (AlN), doped aluminum nitride, lead zirconate titanate, quartz (Quartz), or the like, as non-limiting examples, may be used. The doped aluminum nitride may further include a rare earth metal, a transition metal, or an alkaline earth metal. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). The alkaline earth metal may include magnesium (Mg).

When the content of elements doped into aluminum nitride (AIN) to improve piezoelectric properties is less than 0.1 at %, piezoelectric properties higher than the piezoelectric properties of aluminum nitride (AlN) may not be implemented, and when the content of elements exceeds 30 at %, the manufacturing and composition control for deposition may be difficult such that a non-uniform phase may be formed.

Accordingly, in the example embodiment, the content of elements doped into aluminum nitride (AlN) may be in the range of 0.1 to 30 at %.

In the example, aluminum nitride (AlN) doped with scandium (Sc) may be used for the piezoelectric layer. In this example, the piezoelectric constant may increase such that kₜ² of the acoustic resonator may increase.

The piezoelectric layer 123 according to the example may include the piezoelectric portion 123a disposed in the central portion S, and the bent portion 123b disposed in the extension portion E.

In an example, the piezoelectric portion 123a may be configured to be directly laminated on the upper surface of the first electrode 121. Accordingly, the piezoelectric portion 123a may be interposed between the first electrode 121 and the second electrode 125 and may be disposed to be flat along with the first electrode 121 and the second electrode 125.

The bent portion 123b of the piezoelectric layer 123 may be a region extending outwardly from the piezoelectric portion 123a, and disposed within the extension portion E.

The bent portion 123b may be disposed on the insertion layer 170, and may have a shape in which the upper surface thereof may be raised along the shape of the insertion layer 170. Accordingly, the piezoelectric layer 123 may be bent on the boundary between the piezoelectric portion 123a and the bent portion 123b, and the bent portion 123b may be raised to correspond to the thickness and shape of the insertion layer 170.

The bent portion 123b may be divided into an inclined portion 1231 and an extension portion 1232.

The inclined portion 1231 may refer to a portion that is formed to be inclined along the inclined surface L of the insertion layer 170. Additionally, the extension portion 1232 may refer to a portion that extends outwardly from the inclined portion 1231.

The inclined portion 1231 may be formed parallel to the inclined surface L of the insertion layer 170, and the inclination angle of the inclined portion 1231 may be formed to be the same as the inclination angle of the inclined surface L of the insertion layer 170.

The insertion layer 170 may be disposed along a surface formed by the membrane layer 150, the first electrode 121, and the etch stopper 145. Accordingly, the insertion layer 170 may be partially disposed in the resonant portion 120, and may be disposed between the first electrode 121 and the piezoelectric layer 123.

The insertion layer 170 may be disposed on the periphery of the central portion S of the resonant portion 120, and may support the bent portion 123b of the piezoelectric layer 123. Accordingly, the bent portion 123b of the piezoelectric layer 123 may be divided into the inclined portion 1231 and the extension portion 1232 according to the shape of the insertion layer 170.

In an example, the insertion layer 170 may be disposed in an area other than the central portion S of the resonant portion 120. In an example, the insertion layer 170 may be disposed on the entire region other than the central portion S on the board 110, or may be disposed on a partial region.

The insertion layer 170 may be configured to have a thickness that increases in the direction that extends away from the central portion S of the resonant portion 120. Accordingly, the side surface of the insertion layer 170 that is disposed adjacent to the central portion S may be formed as an inclined surface L having a constant inclination angle a

When the inclination angle θ of the side surface of the insertion layer 170 is smaller than 5°, to manufacture the element, the thickness of the insert layer 170 may have to be significantly reduced or the area of the inclined surface L may have to be excessively increased, which may be difficult to implement.

Additionally, when the inclination angle θ of the side surface of the insertion layer 170 is greater than 70°, the inclination angle of the piezoelectric layer 123 or the second electrode 125 laminated on the insertion layer 170 may be greater than 70°. In this example, since the piezoelectric layer 123 or the second electrode 125 laminated on the inclined surface L may be excessively bent, cracks may be created in the bent portion.

Accordingly, in an example, the inclination angle θ of the inclined surface L may be formed in the range of 5° or more, and 70° or less.

In an example, the inclined portion 1231 of the piezoelectric layer 123 may be formed along the inclined surface L of the insertion layer 170, and may thus have the same inclination angle as the inclination angle of the inclined surface L of the insertion layer 170. Accordingly, the inclination angle of the inclined portion 1231 may also be formed in the range of 5° or more and 70° or less, in a similar manner as the inclined surface L of the insertion layer 170. This configuration may be equally applied to the second electrode 125 laminated on the inclined surface L of the insertion layer 170.

In a non-limited example, the insertion layer 170 may be formed of a dielectric material such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), or the like, and may be formed of a material different from that of the piezoelectric layer 123.

Additionally, the insertion layer 170 may be implemented by a metal material. When the bulk acoustic wave resonator in the example is implemented for 5G communications, since heat may be extensively generated in a resonator, it may be necessary to smoothly radiate the heat generated in the resonant portion 120. Accordingly, the insertion layer 170 in an example may be formed of an aluminum alloy material including scandium (Sc).

Additionally, the insertion layer 170 may be formed as a SiO₂ thin film implanted with nitrogen (N) or fluorine (F).

The resonant portion 120 may be spaced apart from the board 110 and the insulating layer 115 by the cavity C, which may be formed as a void.

The cavity C may be formed by removing a portion of the support layer 140 by supplying an etching gas (or an etching solution) to an inlet hole H (see FIG. 1) during the process of manufacturing the acoustic resonator.

The protective layer 160 may be disposed along the surface of the acoustic resonator 100 and may protect the acoustic resonator 100. The protective layer 160 may be disposed along the surface formed by the second electrode 125 and the bent portion 123b of the piezoelectric layer 123.

The protective layer 160 may be formed as a single layer, or may be formed by laminating two or more layers having different materials if desired. Additionally, the protective layer 160 may be partially removed for frequency control in a final manufacturing process. In an example, the thickness of the protective layer 160 may be adjusted in a frequency trimming process.

In a non-limiting example, as the protective layer 160, a dielectric layer including silicon nitride (Si₃N₄), silicon oxide (SiO₂), magnesium oxide (MgO), zirconium oxide (ZrO₂), aluminum nitride (AlN), lead lyrconate titanate (PZT), gallium arsenide (GaAs), hafnium oxide (HfO₂), aluminum oxide (Al₂O₃), titanium oxide (TiO₂), or zinc oxide (ZnO) may be used, but the example is not limited thereto.

Additionally, when the protective layer 160 is formed as a temperature compensation layer, the protective layer 160 may be formed of one of ZrW₂O₈, ZrV₂O₇, ZrMo₂O₈, HfMo₂O₈, HfW₂O₈, HfV₂O₇, Sc(WO₄)₃, LiAlSiO₄, BiFeO₃.

The first electrode 121 and the second electrode 125 may extend in a direction that is external to the resonant portion 120. Additionally, the first metal layer 180 and the second metal layer 190 may be disposed on the upper surfaces of the extended portions of the respective first electrode 121 and the second electrode 125.

In a non-limiting example, the first metal layer 180 and the second metal layer 190 may be formed of one of gold (Au), a gold-tin (Au—Sn) alloy, copper (Cu), a copper-tin (Cu—Sn) alloy, aluminum (Al), and an aluminum alloy. In an example, the aluminum alloy may be an aluminum-germanium (Al—Ge) alloy or an aluminum-scandium (Al—Sc) alloy.

The first metal layer 180 and the second metal layer 190 may function as a connection wiring that electrically connects the electrodes 121 and 125 of the acoustic resonator in the example to electrodes of another acoustic resonator disposed adjacent to the acoustic resonator 100.

The first metal layer 180 may penetrate the protective layer 160, and may be bonded to the first electrode 121.

Additionally, in the resonant portion 120, the first electrode 121 may have an area larger than an area of the second electrode 125, and the first metal layer 180 may be formed on a peripheral portion of the first electrode 121.

Accordingly, the first metal layer 180 may be disposed along the periphery of the resonant portion 120, and may surround the second electrode 125. However, the one or more examples are not limited thereto.

The resonant portion 120 configured as above may be spaced apart from the board 110 through the cavity C disposed below the membrane layer 150. Accordingly, the membrane layer 150 may be disposed below the first electrode 121 and the insertion layer 170, and may support the resonant portion 120.

The cavity C may be formed as a void, and may be formed by removing a portion of the support layer 140 by supplying an etching gas (or an etching solution) to an inlet hole H (in FIG. 1).

Additionally, in the bulk acoustic wave resonator 100 in the example, at least one temperature compensation layer 130 may be disposed in the resonant portion 120.

Most of the materials forming the resonant portion 120 in the example may have a negative temperature coefficient of elastic constant (TCE).

The TCE may refer to a temperature coefficient for stiffness, and when the TCE is negative, the resonance frequency may decrease as the temperature increases.

Specifically, a plurality of bulk acoustic wave resonators 100 may be combined and used as a filter. In this example, when the Q-value of the bulk acoustic wave resonator 100 is relatively high, the skirt properties to select only a desired band from the filter may improve, and insertion loss and attenuation performance may improve.

Additionally, in the bulk acoustic wave resonator 100, temperature coefficient of frequency (TCF) performance may be important. TCF may be properties indicating a gradual change in the resonant frequency according to the temperature, and may be determined by physical properties of the material.

When the TCF properties is bad (e.g., when the absolute value increases), the change in the resonance frequency may increase according to the temperature change, such that it may be difficult to select only a desired bandwidth. Conversely, as the absolute value of TCF decreases, the change in the resonance frequency according to the temperature change may decrease. Accordingly, it may be desirable to maintain the TCF close to zero as for the bulk acoustic wave resonator.

In the bulk acoustic wave resonator 100, the frequency may be a function of physical properties (density (p) and stiffness (C)) and a thickness (t), and as for a single material, the TCF may be represented as below.

$$\frac{1}{f} \frac{df}{dT} = \frac{1}{2} ( \frac{1}{c} \frac{d c}{dT} - \frac{1}{ρ} \frac{d ρ}{dT} ) - \frac{1}{t} \frac{d t}{dT} = \frac{1}{2} ( \frac{1}{c} \frac{d c}{dT} + \frac{1}{V} \frac{dV}{dT} ) - \frac{1}{t} \frac{dt}{dT} = \frac{1}{2} ( \frac{1}{c} \frac{dc}{dT} + \frac{1}{t} \frac{d t}{dT} ) \qquad Equation 1$$

In an example, V may refer to the volume of the material, T may refer to the temperature, and t may refer to the thickness. Additionally,

$$\frac{1}{f} \frac{d f}{d T}$$

may be the TCF, indicating the temperature coefficient of frequency,

$$\frac{1}{c} \frac{d c}{d T}$$

may be the TCE, indicating the temperature coefficient of elastic constant for stiffness, and

$$\frac{1}{t} \frac{d t}{d T}$$

may be the CTE, indicating a thermal expansion coefficient.

The TCF properties may be determined by TCE and CTE, and in the actual bulk acoustic wave resonator, the TCF may be determined by the influence of the TCE and CTE values of the materials forming the layers and the thickness of each layer. The TCF properties may have a relatively large influence on the TCE.

As described above, most of the materials forming the resonant portion 120 may have a negative TCE. Accordingly, as the temperature of the resonant portion 120 increases, the resonant frequency may decrease, which may be a problem.

The bulk acoustic wave resonator 100 in one or more examples may include at least one temperature compensation layer 130. The bulk acoustic wave resonator 100 in the one or more examples may reduce frequency fluctuations by canceling and compensating the properties of the TCE through the temperature compensation layer 130. Accordingly, the temperature compensation layer 130 in the example embodiment may include a material having a positive TCE.

Table 1 below lists TCE values and CTE values for main materials used in the bulk acoustic wave resonator 100.

TABLE 1

| Material | TCE [ppm/K] | CTE [ppm/K] |
|---|---|---|
| Mo | −130 | +5.6 |
| W | −99 | +4.2 |
| AIN | −60 | +4.4 |
| SiO₂ | +239 | +2.4 |
| Si | −75 | +3.2 |

As indicated in Table 1, most of the materials (ex. Mo/W/AlN/Si/Au/Al, or the like) other than SiO₂ may have negative TCEs (negative numbers), such that, when the temperature increases, frequency may decrease. In the example of SiO₂, the TCE may be positive (a positive number) such that the frequency may increase as the temperature increases.

Accordingly, when the material of the temperature compensation layer 130 is formed of SiO₂, the negative TCE of the piezoelectric layer 123 or the first and second electrodes 121 and 125 included in the resonant portion 120 may cancel out the positive TCE of the material forming the temperature compensation layer 130, such that changes in the TCF properties according to the temperature may be reduced.

The temperature compensation layer 130 in the example may include SiO₂ to provide positive TCE properties.

When the temperature compensation layer 130 is formed of SiO₂, the frequency change with respect to the temperature change may be prevented by compensating the TCE properties, but the viscoelastic loss may increase due to SiO₂ such that the Q-value of the bulk acoustic wave resonator 100 may be reduced.

According to Hook's law (σ=cS), stress σ may be proportional to the strain (S), where a proportionality constant c may refer to stiffness. However, when a vertical wave is generated to resonate the resonant portion 120, when a viscoelastic loss is present in the material in which the vertical wave travels, stress σ may be additionally affected by the rate of change

$$( η \frac{\partial S}{\partial t} )$$

with respect to the time of the strain S. In an example, the proportionality constant η may refer to the viscoelastic loss.

Accordingly, a material having a large viscoelastic loss may lower the traveling speed of the vertical wave, and accordingly, the Q value of the bulk acoustic wave resonator 100 may be reduced. Additionally, since SiO₂ is a dielectric material, not a piezoelectric material, kₜ² performance of the bulk acoustic wave resonator 100 may also be degraded.

Additionally, to implement an accurate resonance frequency, the thickness of the temperature compensation layer 130 may have to be accurately formed. However, when the entire temperature compensation layer 130 is formed of SiO₂, the performance of TCF, Q value, kₜ², or the like, may sensitively change according to the change in the thickness of the temperature compensation layer 130, which may increase process difficulty.

Additionally, the TCF, Q value, and kₜ² performance may depend on a function of the thickness of the temperature compensation layer 130, and accordingly, there may be limitations in designing the TCF, Q value, and kₜ² performance to desired values.

To address the above issue, the temperature compensation layer 130 in the example may include a temperature compensation portion 131 and a loss compensation portion 132.

The temperature compensation portion 131 and the loss compensation portion 132 may be disposed on one layer in the form of a pattern. In the example, SiO₂ may be used as a material of the temperature compensation portion 131.

Accordingly, in the bulk acoustic wave resonator 100 in the example, the temperature compensation portion 131 formed of SiO₂ may be dispersedly disposed in the pattern temperature compensation layer 130 to prevent the frequency fluctuation according to the temperature change, and the loss compensation portion 132 may be disposed between the temperature compensation portions 131 such that loss induced by the temperature compensation portion 131 may be compensated.

In an example, the loss compensation portion 132 may be formed of a piezoelectric material. In an example, the loss compensation portion 132 may be formed of the same material as a material that forms the piezoelectric layer 123. More specifically, in an example, both the piezoelectric layer 123 and the loss compensation portion 132 may be formed of AlN or ScAlN.

Since the temperature compensation portion 131 may be formed of a dielectric, when the temperature compensation portion 131 is disposed between the first electrode 121 and the second electrode 125, the piezoelectric coefficient of the portion 120 may be reduced due to the temperature compensation portion 131. Accordingly, in the example, the loss compensation portion 132 may be formed of a material having a relatively large piezoelectric coefficient, thereby compensating for the piezoelectric performance.

However, is the examples are not limited thereto, and the loss compensation portion 132 may be formed with a material different from a material of the piezoelectric layer 123 if desired.

In an example, the loss compensation portion 132 may be formed of a doped piezoelectric material (e.g., ScAlN), and the piezoelectric layer 123 may be formed of an undoped piezoelectric material (e.g., AlN).

Additionally, the loss compensation portion 132 in the example may be formed of a metal material. Specifically, the loss compensation portion 132 may be formed of the same material as a material of the first electrode 121 or the second electrode 125. In an example, Mo and Ru may be used as the material for the electrodes, and may have low viscoelastic loss, such that degradation of Q value and kt² performance may be reduced. Additionally, since the loss compensation portion 132 may be formed together in the process of forming the first electrode 121 or the second electrode 125 during the manufacturing process, the bulk acoustic wave resonator, the loss compensation portion 132 may be easily implemented in terms of process.

As such, the loss compensation portion 132 in the example may be formed of a piezoelectric material or a metal material, and if desired, the loss compensation portion 132 may be formed of one of the piezoelectric layer 123, the first electrode 121, and the second electrode 125. However, the example is not limited thereto.

Additionally, with respect to the Temperature Coefficient of Elastic Constant (TCE), the temperature compensation portion 131 in the example may be formed of a material having a positive TCE, and the loss compensation portion 132 may be formed of a material having a negative TCE.

In the example, the pattern of the temperature compensation layer 130 may include a stripe pattern. In an example, in the temperature compensation layer 130, each of the temperature compensation portion 131 and the loss compensation portion 132 may include a plurality of linear patterns, and the linear patterns of the temperature compensation portion 131 and the linear patterns of the loss compensation portion 132 may be alternately disposed.

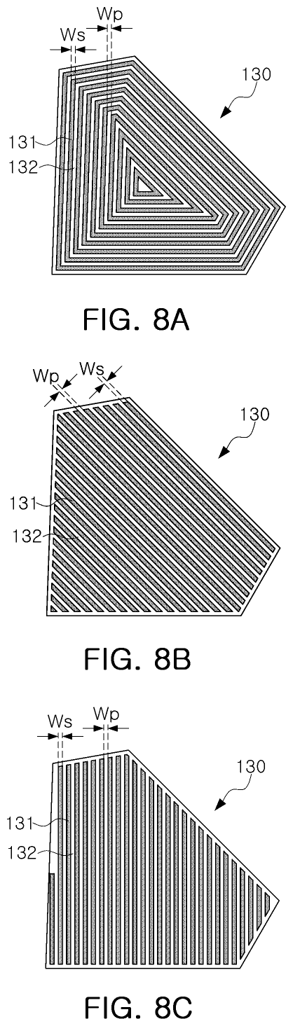

FIGS. 8A-8C illustrate plan diagrams of a temperature compensation layer, in accordance with one or more embodiments.

Referring to FIG. 8A, the temperature compensation layer 130 in the example may have an annular shape with a concentric linear pattern. In this example, the normal direction of the linear pattern and the traveling direction of the lateral wave may match, such that an implementation that prevents or increases the lateral wave by adjusting the spacing between the patterns, may be added.

However, the examples are not limited thereto, and as illustrated in FIG. 8B, the linear patterns may be disposed parallel to one side of the polygonal shape formed by the resonant portion, or as illustrated in FIG. 8C, the linear pattern may be disposed without consideration of the side of a polygonal shape. FIGS. 8B and 8C illustrate the example in which the temperature compensation portion 131 may be disposed along the outline of the polygonal shape. However, the example is not limited thereto, and the loss compensation portion 132 may be disposed or a linear pattern may be alternately disposed on the outline of the polygonal shape.

In the example, the temperature compensation layer 130 may be disposed between the first electrode 121 and the second electrode 125. However, the example is not limited thereto, and if desired, the temperature compensation layer 130 may be disposed below the first electrode 121 or above the second electrode 125.

In an example, the temperature compensation layer 130 may be disposed between the piezoelectric layer 123 and the second electrode 125, which may be disposed above the piezoelectric layer 123. However, the example is not limited thereto, and the temperature compensation layer 130 may be disposed between the first electrode 121 and the piezoelectric layer 123, disposed below the piezoelectric layer 123, or may be disposed in the piezoelectric layer 123.

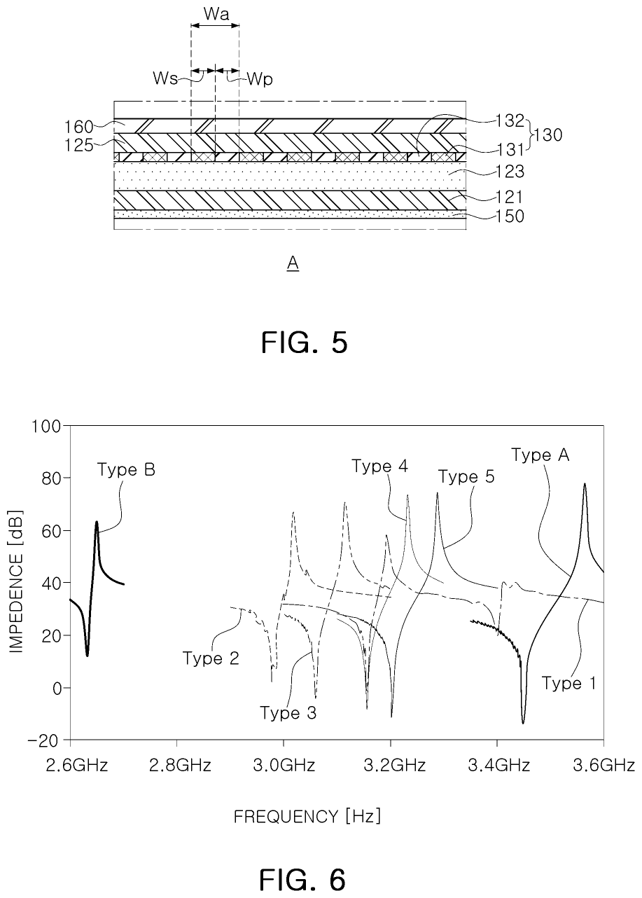

Additionally, referring to FIG. 5, an entire width Wa of the unit pattern, which is a sum of a width Ws of the unit pattern of the temperature compensation portion 131 and a width Wp of the unit pattern of the loss compensation portion 132, may be smaller than a wavelength of a lateral wave generated when the bulk acoustic wave resonator 100 is driven.

In an example, the unit pattern may refer to one of a plurality of linear patterns formed by the temperature compensation portion 131 or the loss compensation portion 132. Additionally, in the description below, a unit pattern of the temperature compensation layer 130 may include a unit pattern of the temperature compensation portion 131 and a unit pattern of the loss compensation portion 132. Accordingly, the width of the unit pattern of the temperature compensation layer 130 may refer to Wa in FIG. 5.

Typically, the frequency band in which the filter implementing the bulk acoustic wave resonator 100 is mainly used, was 1.75 GHz to 3.55 GHz, and the wavelength of the lateral wave near the resonance and anti-resonance frequencies was about 1 μm to 4 μm.

The lateral wave may be naturally generated by properties of the material when the bulk acoustic wave resonator resonates and generates a vertical wave. Such a lateral wave may travel in the plane direction (or a horizontal direction) of the resonator, may form a specific wave length and may form a specific mode through mode conversion. A lateral wave between a resonant frequency and an anti-resonant frequency in the above frequency band may include four modes.

Accordingly, in the example, the width Wa of the unit pattern of the temperature compensation layer 130 may be formed to be equal to, or less than, the wavelength of the lateral wave, thereby preventing partial resonance. Accordingly, stable resonance driving may be implemented, and a temperature compensation effect and a loss compensation effect may be provided.

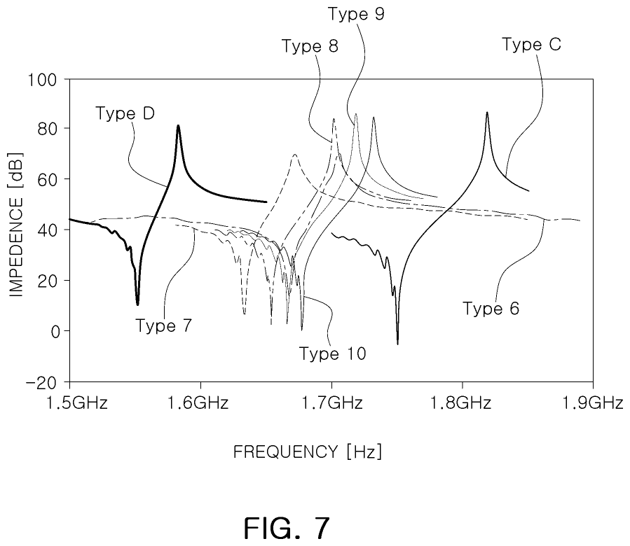

FIG. 6 is a diagram illustrating changes in an impedance waveform according to presence or absence of a temperature compensation layer and changes in a size of a pattern, illustrating a 3.55 GHz band.

The waveform (Type A) on the rightmost side in FIG. 6 may be a waveform for the structure without the temperature compensation layer 130, and the waveform (Type B) on the leftmost side may be a waveform for the structure in which the entire temperature compensation layer 130 may be formed of SiO₂ and may be disposed between the piezoelectric layer 123 and the second electrode 125.

The waveforms therebetween may be the waveform for the structure in which the temperature compensation layer 130 includes the temperature compensation portion 131 and the loss compensation portion 132, and may be an impedance waveform according to changes in the width of the unit patterns Ws and Wp of the temperature compensation portion 131 and the loss compensation portion 132.

Referring to FIG. 6, when the width Ws of the unit pattern of the temperature compensation portion 131 was 1.0 um and the width Wp of the unit pattern of the loss compensation portion 132 was 1.0 um (Type 1), it is indicated that two resonance peaks were present in the impedance waveform, which may be because the vertical wave generated from the resonant portion 120 was divided into a vertical wave traveling to the temperature compensation portion 131 and a vertical wave traveling to the loss compensation portion 132 while the vertical wave passed through the temperature compensation layer 130, and which may be caused by the two resonant modes due to partial resonance.

When the width Ws of the unit pattern of the temperature compensation portion 131 was 0.5 um and the width Wp of the unit pattern of the loss compensation portion 132 was 0.5 μm (Type 2), that is, the width Wa of the unit pattern of the temperature compensation layer 130 was 1.0 μm, only one resonance peak appeared in the impedance waveform, and some noise appeared throughout the waveform. Accordingly, when the width Wa of the unit pattern of the temperature compensation layer 130 exceeds 1.0 μm, it may be difficult to maintain stable resonance.

When the width Ws of the unit pattern of the temperature compensation portion 131 was configured to be 0.4 μm, and the width Wp of the unit pattern of the loss compensation portion 132 was configured to be 0.4 μm (Type 3), noise was removed and the waveform was restored to the waveform similar to the waveform of Type A in which the temperature compensation layer 130 was not used.

It is indicated that a similar trend appeared in Type 4 (Ws: 0.2 μm, Wp: 0.2 μm) and Type 5 (Ws: 0.1 μm, Wp: 0.1 μm), in which a unit pattern was formed with a smaller width.

It is confirmed that the wavelength of the lateral wave generated in the bulk acoustic wave resonator in the 3.55 GHz band may be in the range of about 1 um to 2.2 μmm. Additionally, as described above, when the width Wa of the unit pattern of the temperature compensation layer 130 exceeds 1.0 μm, it may be difficult to maintain stable resonance.

Accordingly, the width Wa of the unit pattern of the temperature compensation layer 130 in the 3.55 GHz band may be defined as a size of 1 μm or less, which is the minimum wavelength of a lateral wave.

Additionally, as in Type 2 illustrated in FIG. 6, when the width of the unit pattern of the temperature compensation portion 131 was configured to be 0.4 μm or less, and the width of the unit pattern of the loss compensation portion 132 was configured to be 0.4 μm or less, that is, when the width Wa of the unit pattern of the temperature compensation layer 130 was 0.8 μm or less, stable resonance was implemented without partial resonance, and the effect of temperature compensation and loss compensation was obtained.

Accordingly, in the example, the width Wa of the unit pattern of the temperature compensation layer 130 may be configured to be 0.8 μm or less. In an example, in the 3.55 GHz band, the width Wa of the unit pattern of the temperature compensation layer 130 may be configured to be 80% or less of the wavelength of the lateral wave generated by the resonant portion 120.

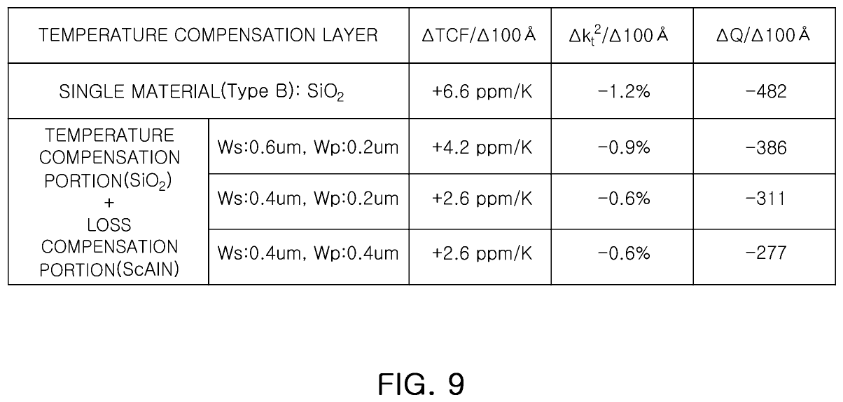

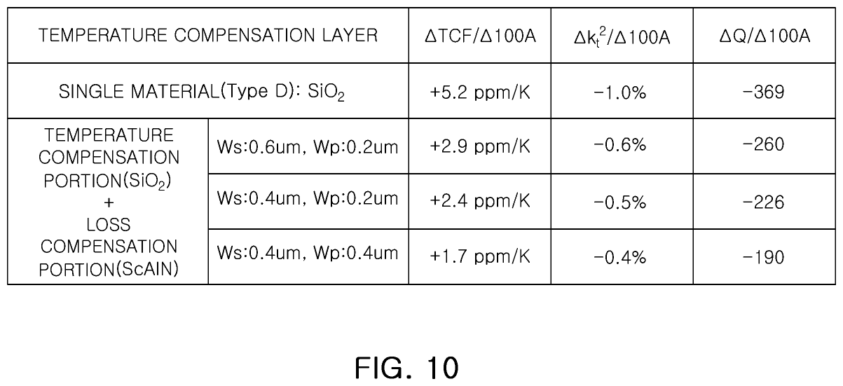

In the example, the unit pattern of the temperature compensation portion 131 and the unit pattern of the loss compensation portion 132 may have the same width. However, the example is not limited thereto. In an example, as illustrated in FIGS. 9 and 10, the unit pattern of the temperature compensation portion 131 and the unit pattern of the loss compensation portion 132 may have different widths. In an example, one of the width Ws of the unit pattern of the temperature compensation portion 131 and the width Wp of the unit pattern of the loss compensation portion 132 may be 0.4 μm or less, and accordingly, one of the width Ws of the unit pattern of the temperature compensation portion 131 and the width Wp of the unit pattern of the loss compensation portion 132 may be 40% or less of the wavelength of the lateral wave generated by the resonant portion 120.

Additionally, according to Type 3 to Type 5, it is confirmed that, when the width Wa of the unit pattern of the temperature compensation layer 130 was 0.2 μm or more and 0.8 μm or less, that is, the lateral wave generated in the resonant portion 120 was in the range of 80-20%, stable resonance was implemented without partial resonance, and the effect of temperature compensation and loss compensation was obtained.

The lower limit of the above range may be merely based on Type 5, and the lower limit of the width Wa of the unit pattern in the example is not limited to 0.2 μm. In consideration of the overall trend of the waveform illustrated in FIG. 6, it is illustrated that the impedance waveform approaches Type A as the width Wa of the unit pattern decreases.

Accordingly, even when the width Wa of the unit pattern is configured to be 0.2 μm or less, it is easily inferred that the above-described effect may be obtained, and accordingly, the width Wa of the unit pattern may include a range of 0.2 μm or less.

FIG. 7 is a diagram illustrating changes in an impedance waveform according to presence or absence of a temperature compensation layer and changes in a size of a pattern, illustrating a 1.75 GHz band, a relatively low frequency region.

As in FIG. 6, the rightmost waveform (Type C) illustrated in FIG. 7 may be a waveform illustrating the structure without the temperature compensation layer 130, and the leftmost waveform (Type D) may be a waveform illustrating the structure in which the entire temperature compensation layer 130 may be formed of SiO₂ and may be disposed between the piezoelectric layer 123 and the second electrode 125.

The waveforms therebetween may be a waveform illustrating the structure in which the temperature compensation layer 130 includes the temperature compensation portion 131 and the loss compensation portion 132, and may be an impedance waveform according to the change in the widths Ws and Wp of the unit patterns of the temperature compensation portion 131 and the loss compensation portion 132.

Referring to FIG. 7, when the width Ws of the unit pattern of the temperature compensation portion 131 was configured to be 1.2 μm and the width Wp of the unit pattern of the loss compensation portion 132 was configured to be 1.2 μm (Type 6), the impedance waveform was distorted, and several resonance peaks appeared in the outer frequency section of the resonance point and the anti-resonance point, which may be because the vertical wave generated from the resonant portion 120 was divided into the a vertical wave traveling to the temperature compensation portion 131 and a vertical wave traveling to the loss compensation portion 132 while the vertical wave passed through the temperature compensation layer 130, and which may be caused by several resonant modes due to partial resonance.

It is indicated that, when the width Ws of the unit pattern of the temperature compensation portion 131 was configured to be 1.0 μm and the width Wp of the unit pattern of the loss compensation portion 132 was configured to be 1.0 μm (Type 7), that is, when the width Wa of the unit pattern of the temperature compensation layer 130 is 2.0 μm, only one resonance peak appeared, and waveform distortion appeared in the outer portion of the anti-resonance point, and the impedance at the anti-resonance point was not sufficient. Accordingly, when the width Wa of the unit pattern of the temperature compensation layer 130 exceeds 2.0 μm, it may be difficult to maintain stable resonance.

In an example, when the width of the unit pattern of the temperature compensation portion 131 was 0.8 μm and the width of the unit pattern of the loss compensation portion 132 was 0.8 μm (Type 8), that is, the width Wa of the unit pattern of the temperature compensation 130 was 1.6 μm, the waveform distortion disappeared and the waveform was restored to a waveform similar to that of Type C in which the temperature compensation layer 130 was not used.

Additionally, the same trend appeared in Type 9 (Ws: 0.6 μm, Wp: 0.6 μm) and Type 10 (Ws: 0.4 μm, Wp: 0.4 μm) in which the unit pattern was formed with a smaller width.

The wavelength of the lateral wave generated in the bulk acoustic wave resonator in the 1.75 GHz band was in the range of about 2 μm to 4 μm. Additionally, as described above, when the width Wa of the unit pattern of the temperature compensation layer 130 exceeds 2.0 μm, it may be difficult to maintain stable resonance.

Accordingly, the width Wa of the unit pattern of the temperature compensation layer 130 in the 1.75 GHz band may be configured to be a size of 2 μm or less, which may be the minimum wavelength of a lateral wave.

Additionally, as in Type 8 illustrated in FIG. 7, when the width of the unit pattern of the temperature compensation portion 131 is 0.8 μm or less and the width of the unit pattern of the loss compensation portion 132 is 0.8 μm or less, that is, when the width Wa of the unit pattern of the temperature compensation layer 130 is 1.6 μm or less, stable resonance may be implemented without partial resonance, and the effect of temperature compensation and loss compensation may be obtained.

Accordingly, in the example, the width Wa of the unit pattern of the temperature compensation layer 130 may be configured to be 1.6 μm or less. In an example, in the 1.75 GHz band, the width Wa of the unit pattern of the temperature compensation layer 130 may be configured to be 80% or less of the wavelength of the lateral wave generated by the resonant portion 120.

In the example, the width Ws of the unit pattern of the temperature compensation portion 131 and the width Wp of the unit pattern of the loss compensation portion 132 may be configured to be the same. However, the example is not limited thereto. In an example, as illustrated in FIGS. 9 and 10, the unit pattern of the temperature compensation portion 131 and the unit pattern of the loss compensation portion 132 may have different widths. In an example, one of the width Ws of the unit pattern of the temperature compensation portion 131, and the width Wp of the unit pattern of the loss compensation portion 132 may be configured to be 0.8 μm or less, and accordingly, one of the width Ws of the unit pattern of the temperature compensation portion 131 and the width Wp of the unit pattern of the loss compensation portion 132 may be configured to be 40% or less of the wavelength of the lateral wave generated by the resonant portion 120.

Additionally, according to Type 8 to Type 10, when the width Wa of the unit pattern of the temperature compensation layer 130 is 0.8 μm or more and 1.6 μm or less, that is, the width Wa of the unit pattern of the temperature compensation layer 130 is configured to be in the range of 40-80%, stable resonance may be implemented without partial resonance, and the effect of temperature compensation and loss compensation may be obtained.

The lower limit of the above range may be merely based on Type 10, and the lower limit of the width Wa of the unit pattern in the example is not limited to 0.8 μm. In consideration of the overall trend of the waveform illustrated in FIG. 7, the impedance waveform approaches Type C as the width Wa of the unit pattern decreases.

Accordingly, it is inferred that even when the width Wa of the unit pattern is configured to be 0.8 μm or less, the above-described effect may be obtained, and accordingly, the width Wa of the unit pattern may include a range of 0.8 um or less.

FIG. 9 illustrates a table of data of TCF, kₜ², and Q values according to changes in a thickness of a temperature compensation layer in a resonant frequency band of 3.55 GHz. FIG. 10 illustrates a table of data of TCF, kₜ², and Q values according to changes in a thickness of a temperature compensation layer in a resonant frequency band of 1.75 GHz.

Referring to FIGS. 9 and 10, differently from Type B and Type D in which the entire temperature compensation layer 130 was formed of SiO₂ in both the 3.55 GHz band and the 1.75 GHz band, the changes in the TCF, kt2, and Q values of the bulk acoustic wave resonator in which the temperature compensation portion 131 and the loss compensation portion 132 are disposed in the linear pattern decreased. Accordingly, it is indicated that sensitivity of the TCF, kₜ², and Q values according to the change in the thickness of the temperature compensation layer 130 was relieved.

Accordingly, in the example, the frequency fluctuation through the temperature compensation portion 131 may be reduced, and additionally, the degradation of the TCF, kₜ², and Q values may be reduced through the loss compensation portion 132. Additionally, sensitivity of the TCF, kₜ², and Q values according to the change in the thickness of the temperature compensation layer 130 may be alleviated, such that the difficulty of the manufacturing process may be reduced.

In the bulk acoustic wave resonator in the example, the temperature compensation layer 130 may be formed of a material having TCE properties opposite to that of a different material, such that changes in the resonance frequency according to the temperature change may be reduced.

Additionally, since the temperature compensation layer 130 includes the temperature compensation portion 131 and the loss compensation portion 132, the degradation of the Q value and kₜ² performance may be reduced by including the temperature compensation layer 130.

Additionally, since the width Wa of the unit pattern of the temperature compensation layer 130 may be configured to have a size equal to, or less than, the wavelength of the lateral wave, partial resonance generated due to the temperature compensation layer 130 may be reduced such that stable resonance may be implemented.

Since the temperature compensation layer 130 in the example may be disposed between the second electrode 125 and the piezoelectric layer 123, the piezoelectric layer 123 may not affect crystal orientation, such that the Q value may be maintained. However, the example is not limited thereto.

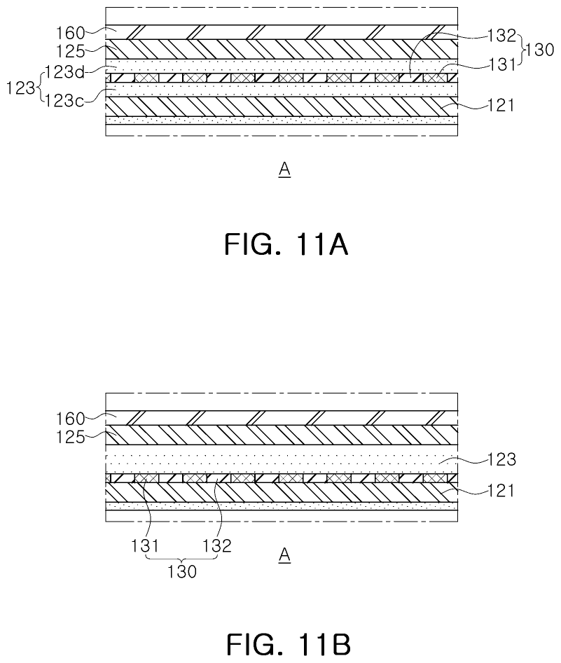

FIGS. 11A and 11B illustrate a cross-sectional diagram of an example bulk acoustic wave resonator, in accordance with one or more embodiments, illustrating a cross-sectional diagram corresponding to FIG. 5.

In the example bulk acoustic wave resonator illustrated in FIG. 11A, the temperature compensation layer 130 may be disposed in the piezoelectric layer 123. The piezoelectric layer 123 may be divided into a first piezoelectric layer 123c disposed between the first electrode 121 and the temperature compensation layer 130, and a second piezoelectric layer 123d disposed between the temperature compensation layer 130 and the second electrode 125.

In an example, the first piezoelectric layer 123c and the second piezoelectric layer 123d may be formed of the same material. However, the examples are not limited thereto, and may be formed of different materials if desired.

In an example, the temperature compensation layer 130 may be configured in the same manner as in the above-described example. In an example, the loss compensation portion 132 may be formed of the same material as a material of the first piezoelectric layer 123c or the second piezoelectric layer 123d.

When the resonance driving of the resonant portion 120 is implemented, stress may be the greatest in the center of the piezoelectric layer. Accordingly, when the temperature compensation layer 130 is disposed between the piezoelectric layers 123, the temperature compensation effect may increase.

In the example bulk acoustic wave resonator illustrated in FIG. 11B, the temperature compensation layer 130 may be disposed between the first electrode 121 and the piezoelectric layer 123. In this example, the temperature compensation layer 130 may be formed relatively early in the process of manufacturing the bulk acoustic wave resonator. Accordingly, the issues caused by forming the temperature compensation layer 130 may be reduced, thereby reducing the difficulty of the process.

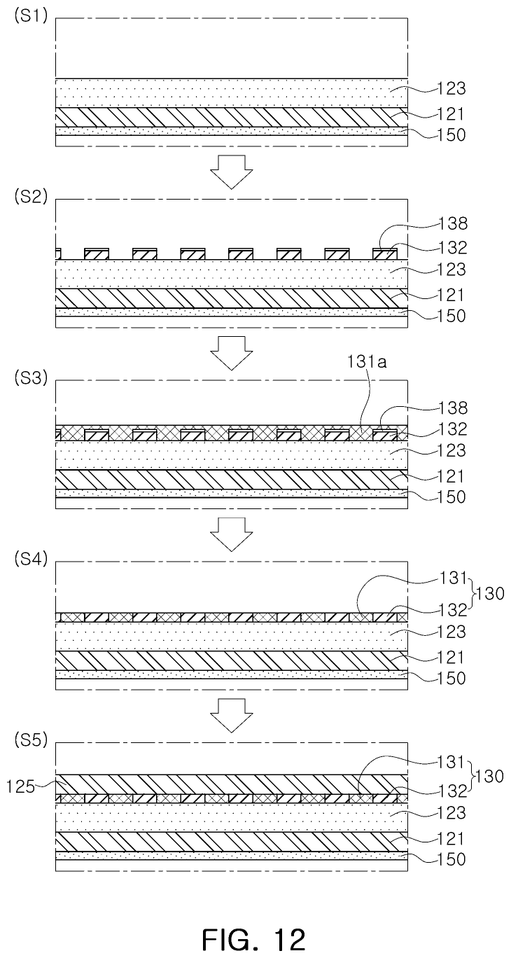

FIG. 12 is a diagram illustrating an example method of manufacturing the bulk acoustic wave resonator illustrated in FIG. 5.

Referring to FIG. 12, process S1 of sequentially laminating the first electrode 121 and the piezoelectric layer 123 may be performed.

Thereafter, process S2 of forming the loss compensation portion 132 may be performed. This process may include forming a material to form or dispose the loss compensation portion 132 on the piezoelectric layer 123 to have a predetermined thickness, and partially removing the corresponding layer using a mask 138.

Process S3 of filling a dielectric 131a such as SiO₂ in a region between the loss compensation portions 132 may be performed. The dielectric 131a may be formed as the temperature compensation portion 131.

Thereafter, the process S4 of removing the dielectric 131a and the mask 138 such that the loss compensation portion 132 is exposed may be performed, thereby forming the temperature compensation layer 130.

Thereafter, process S5 of laminating the second electrode 125 on the temperature compensation layer 130 may be performed, and the protective layer 160 and other elements may be laminated in order on the second electrode 125, thereby manufacturing the bulk acoustic wave resonator illustrated in FIG. 5.

The bulk acoustic wave resonator in the one or more examples described above may be implemented as a filter to filter a specific frequency band in a radio module (RF Module) of a mobile device such as a mobile phone. However, the one or more examples are not limited thereto.

According to the aforementioned examples, the bulk acoustic wave resonator may include the temperature compensation layer formed of a material having TCE properties opposite to materials or properties of other elements of the resonant portion, such that fluctuations in the resonant frequency according to changes in temperature may be reduced.

Additionally, the unit pattern of the temperature compensation layer may be formed to have a size smaller than the wavelength of the lateral wave, such that partial resonance generated due to the temperature compensation layer may be reduced, such that stable resonance may be implemented.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure

What is claimed is:

1. A bulk acoustic wave resonator, comprising:
a board;
a resonant portion comprising a first electrode, a piezoelectric layer, and a second electrode disposed on the board; and
a temperature compensation layer disposed on the resonant portion,
wherein the temperature compensation layer comprises a temperature compensation portion formed of a dielectric, and a loss compensation portion formed of a material different from a material of the temperature compensation portion, and
wherein each of the temperature compensation portion and the loss compensation portion comprises a plurality of linear patterns, and the linear patterns of the temperature compensation portion and the linear patterns of the loss compensation portion are alternately disposed.

2. The bulk acoustic wave resonator of claim 1, wherein a sum of a width of a unit pattern of the temperature compensation portion and a width of a unit pattern of the loss compensation portion is configured to be less than a wavelength of a lateral wave generated in the resonant portion.

3. The bulk acoustic wave resonator of claim 1, wherein a sum of a width of a unit pattern of the temperature compensation portion and a width of a unit pattern of the loss compensation portion is configured to be 0.8 μm or less.

4. The bulk acoustic wave resonator of claim 1, wherein one of a width of the unit pattern of the temperature compensation portion and a width of the unit pattern of the loss compensation portion is configured to be 0.4 μm or less.

5. The bulk acoustic wave resonator of claim 1, wherein a sum of a width of a unit pattern of the temperature compensation portion and a width of a unit pattern of the loss compensation portion is configured to be 1.6 μm or less.

6. The bulk acoustic wave resonator of claim 1, wherein one of a width of the unit pattern of the temperature compensation portion and a width of the unit pattern of the loss compensation portion is configured to be 0.8 μm or less.

7. The bulk acoustic wave resonator of claim 1, wherein a sum of a width of a unit pattern of the temperature compensation portion and a width of a unit pattern of the loss compensation portion is 80% or less of a wavelength of a lateral wave generated in the resonant portion.

8. The bulk acoustic wave resonator of claim 1, wherein one of a width of the unit pattern of the temperature compensation portion and a width of the unit pattern of the loss compensation portion is 40% or less of a wavelength of a lateral wave generated in the resonant portion.

9. The bulk acoustic wave resonator of claim 1, wherein the temperature compensation portion comprises SiO₂.

10. The bulk acoustic wave resonator of claim 1, wherein the loss compensation portion is formed of the same material as a material of one of the piezoelectric layer, the first electrode, and the second electrode.

11. The bulk acoustic wave resonator of claim 1, wherein the loss compensation portion is formed of aluminum nitride (AlN) or scandium doped AlN (ScAlN).

12. The bulk acoustic wave resonator of claim 1, wherein the loss compensation portion is formed of one of a piezoelectric material and a metal.

13. The bulk acoustic wave resonator of claim 1, wherein the temperature compensation layer is disposed between the first electrode and the piezoelectric layer, or between the second electrode and the piezoelectric layer.

14. The bulk acoustic wave resonator of claim 1, wherein each of the linear patterns of the temperature compensation portion and each of the linear patterns of the loss compensation portion are configured to have a concentric annular shape.

15. The bulk acoustic wave resonator of claim 1,
wherein a plane of the resonant portion is configured to have a polygonal shape, and
wherein the linear patterns of the temperature compensation portion and the linear patterns of the loss compensation portion are disposed parallel to one of sides forming the polygonal shape.

16. A bulk acoustic wave resonator, comprising:
a board;
a resonant portion comprising a first electrode, a piezoelectric layer, and a second electrode which are sequentially disposed on the board; and
a temperature compensation layer disposed on the resonant portion,
wherein the temperature compensation layer comprises a temperature compensation portion and a loss compensation portion alternately disposed linearly, and
wherein the temperature compensation portion is formed of a material having a positive temperature coefficient of elastic constant (TCE), and the loss compensation portion is formed of a material having a negative TCE.

17. The bulk acoustic wave resonator of claim 16,
wherein the temperature compensation layer is disposed above the piezoelectric layer, below the piezoelectric layer, or in the piezoelectric layer, and
wherein the piezoelectric layer is formed of a material having a negative TCE.

18. The bulk acoustic wave resonator of claim 16, wherein the piezoelectric layer is formed of aluminum nitride (AlN), and the loss compensation portion is formed of scandium doped AlN (ScAlN).
